(19) United States
(12) Patent Application Publication
(10) Pub. No.: US 2008/0282119 A1
(43) Pub. Date: Nov. 13, 2008

(54) MEMORY DEVICE AND BUILT IN SELF-TEST METHOD OF THE SAME

(76) Inventors: Takahiro Suzuki, Chigasaki-shi (JP); Shinya Fujisawa, Hino-shi (JP); Shoichiro Hashimoto, Tokyo (JP); Tokumasa Hara, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/877,188

(22) Filed: Oct. 23, 2007

(30) Foreign Application Priority Data
Oct. 24, 2006 (JP) 2006-288976

(51) Int. Cl. G11C 29/12; G06F 11/27

(52) U.S. Cl. 714/718; 714/E11.169

(57) ABSTRACT

A memory device including, a nonvolatile memory which stores a step item, a parameter start address, and a parameter which has an address corresponding to the parameter start address and defines the step item, and a controller which performs, on the nonvolatile memory, a test step corresponding to the step item defined by the parameter, the controller being formed in the same chip as the nonvolatile memory.

### CROSS-REFERENCE TO RELATED APPLICATIONS

This application is based upon and claims the benefit of priority from prior Japanese Patent Application No. 2006-288976, filed Oct. 24, 2006, the entire contents of which are incorporated herein by reference.

### BACKGROUND OF THE INVENTION

1. Field of the Invention

The present invention relates to a memory device and a self-test method of the same, and is applied to, e.g., a NOR flash memory.

2. Description of the Related Art

Conventionally, a memory device such as a memory chip on which, e.g., a NOR flash memory is mounted must undergo a sorting test of testing whether the flash memory can normally function. However, this sorting test requires a very long time for one memory chip (one chip), so the test cost increases. Therefore, a BIST (Built In Self-Test) that conducts the sorting test by using a built-in test circuit of a memory chip is performed.

Although the BIST can test a large amount of memory chips, the number of test pins by which a memory chip and tester can contact each other is very small. This makes the BIST unsuitable for a test that serially inputs a large amount of information to one memory chip.

In a sorting test for a nonvolatile memory such as a NOR flash memory, a large number of test steps must be performed to sort many failure modes such as a write characteristic abnormality, erase characteristic abnormality, retention (charge holding) defect, endurance (repetitive rewrite) defect, disturbance defect, and fabrication process defect. Therefore, each test step has many parameters for executing, e.g., cut point, write, and erase, and these parameters are changed many times to increase the yield.

If, however, the contents of test steps are changed or added or the order of the test steps is changed, various circuits including the test circuit must be redesigned in order to cope with the change. Consequently, circuit correction occurs whenever a test step is changed, and this often increases the fabrication cost.

Note that Jpn. Pat. Appln. KOKAI Publication No. 2000-321332 is an example of the well-known inventions related to the invention of this application. Jpn. Pat. Appln. KOKAI Publication No. 2000-321332 describes an evaluation method and evaluation apparatus for efficiently evaluating whether a semiconductor device is normally operable, on the basis of its operation parameters.

### BRIEF SUMMARY OF THE INVENTION

A memory device according to an aspect of the present invention comprises a memory device comprising:

a nonvolatile memory which stores a step item, a parameter start address, and a parameter which has an address corresponding to the parameter start address and defines the step item; and

a controller which performs, on the nonvolatile memory, a test step corresponding to the step item defined by the parameter, the controller being formed in the same chip as the nonvolatile memory.

A built in self-test method of a memory device according another aspect of the present invention comprises a built in self-test method with a memory device including, in the same chip, a nonvolatile memory which stores a step item, a parameter start address, and a parameter which has an address corresponding to the parameter start address and defines the step item, and a controller, the method comprising causing the controller to perform, on the nonvolatile memory, a test step corresponding to the step item defined by the parameter.

According to an aspect of the present invention, there is provided a memory device comprising a nonvolatile memory which stores a step item, a parameter start address, and a parameter which has an address corresponding to the parameter start address and defines the step item, and a controller which performs, on the nonvolatile memory, a test step corresponding to the step item defined by the parameter, the controller being formed in the same chip as the nonvolatile memory.

According to another aspect of the present invention, there is provided a built in self-test method with a memory device including, in the same chip, a nonvolatile memory which stores a step item, a parameter start address, and a parameter which has an address corresponding to the parameter start address and defines the step item, and a controller, the method comprising causing the controller to perform, on the nonvolatile memory, a test step corresponding to the step item defined by the parameter.

### BRIEF DESCRIPTION OF THE SEVERAL VIEWS OF THE DRAWING

FIG. 1 is a block diagram showing a memory device according to an embodiment of the present invention;

FIG. 2 is a view showing an example of the configuration of a NOR flash memory (nonvolatile memory) shown in FIG. 1;

FIG. 3 is a view showing an example of the memory map of a step cell area shown in FIG. 2;

FIG. 4 is a view showing an example of the memory map of a parameter cell area shown in FIG. 2;

FIG. 5 is a flowchart for explaining a BIST (self-test) method of the memory device according to the embodiment;

FIG. 6 is a view showing the way the BIST (self-test) method of the memory device according to the embodiment is performed;

FIG. 7 is a view showing a BIST command format according to the embodiment;

FIG. 8 is a view showing the way step items and parameters of the memory device according to the embodiment are changed;

FIG. 9 is a view showing an example of the changed memory map of the step cell area of the memory device according to the embodiment; and

FIG. 10 is a view showing an example of the changed memory map of the parameter cell area of the memory device according to the embodiment.

### DETAILED DESCRIPTION OF THE INVENTION

An embodiment of the present invention will be explained below with reference to the accompanying drawing. Note that in this explanation, the same reference numerals denote the same parts throughout the drawing.

### Embodiment

### Example of Memory Device Incorporating NOR Flash Memory

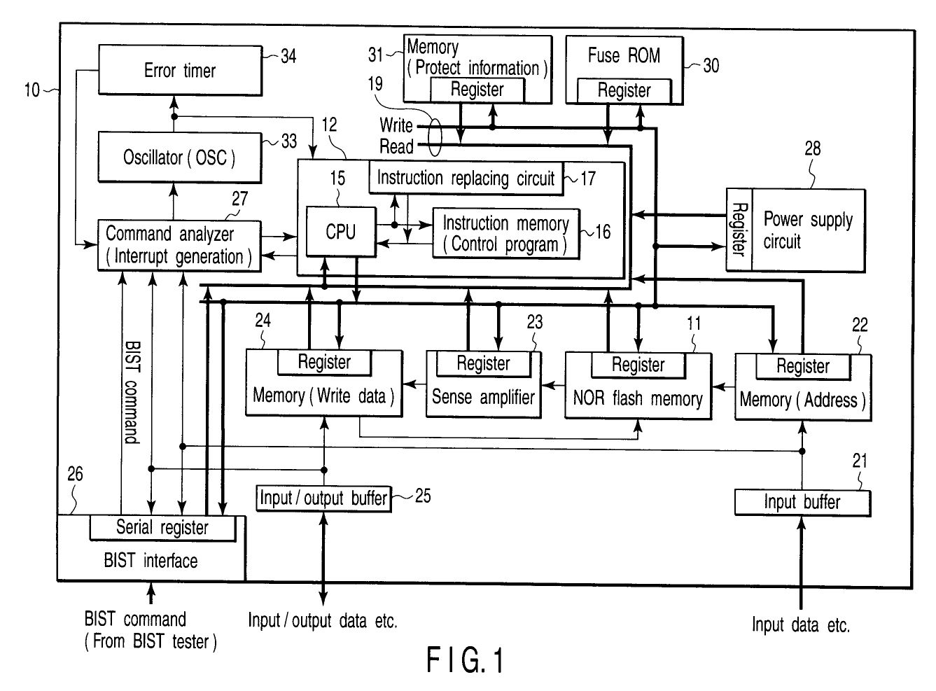

First, an example of the arrangement of a memory device according to an embodiment of the present invention will be explained with reference to FIGS. 1 to 4. This embodiment will be explained by taking a memory device incorporating a NOR flash memory as an example. FIG. 1 is a block diagram showing the memory device according to this embodiment.

### <1. Example of Arrangement>

### 1-1. Example of Arrangement of Memory Device

First, an example of the arrangement of the memory device according to this embodiment will be explained. As shown in FIG. 1, a memory device 10 according to this embodiment comprises a NOR flash memory (nonvolatile memory) 11, a controller 12, an input buffer 21, memories 22, 24, and 31, a sense amplifier 23, an input/output buffer 25, a BIST interface 26, a command analyzer 27, a power supply circuit 28, a fuse ROM 30, an oscillator 33, and an error timer 34 in the same chip.

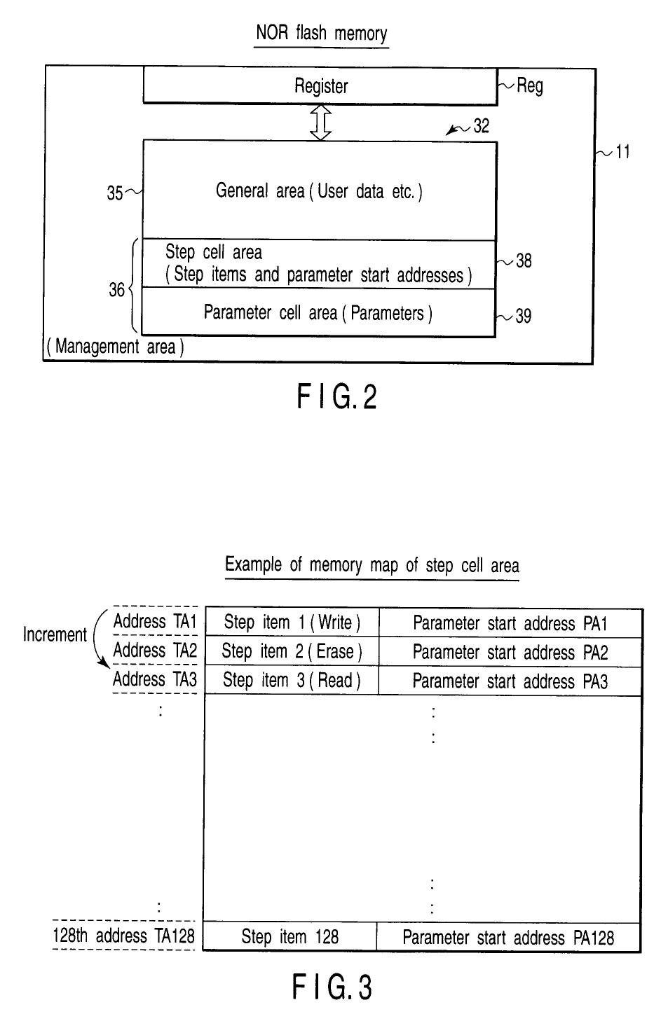

As shown in FIG. 2, the NOR flash memory 11 has a register Reg and memory cell array 32. The memory cell array 32 has a plurality of memory cell transistors (not shown) arranged in a matrix at the intersections of word lines and bit lines. Unlike in a NAND flash memory and the like, random access can be performed in the NOR flash memory because the memory cell transistors are arranged at the intersections of the write lines as described above. Each memory cell transistor has a stacked structure including a floating gate formed on a semiconductor substrate, an inter-electrode insulating film formed on the floating electrode, and a control electrode formed on the inter-electrode insulating film.

The controller 12 comprises a CPU 15, instruction memory 16, and instruction replacing circuit 17. The controller 12 is a microcomputer configured to perform, on the NOR flash memory 11, test steps corresponding to step items defined by parameters.

The CPU 15 controls the whole of the controller 12. The instruction memory 16 stores a control program for the step items.

The input buffer 21 temporarily holds, e.g., input data, addresses, and commands supplied from outside the memory device 10.

Each of the memories 22, 24, and 31 has a register and stores addresses, write data, and protect information. The protect information determines whether the NOR flash memory 11 is programmable.

The sense amplifier 23 has a register, amplifies write/read data from the memory 11 via the register, and transmits the amplified data to a bus 19.

The input/output buffer 25 temporarily holds input/output data, addresses, commands, and the like supplied from outside the memory device 10.

The BIST (Built In Self-Test) interface 26 has a serial register, and transmits, to the command analyzer 27, a BIST command (a test command to be described later) transmitted from a BIST tester.

The command analyzer 27 analyzes the BIST command transmitted from the BIST interface 26, and transmits the analyzed command to the controller 12.

The power supply circuit 28 generates a predetermined power supply voltage for driving the circuits such as the NOR flash memory 11 in the memory device 10.

The fuse ROM 30 stores initial data such as initialization information as nonvolatile data.

The oscillator (OSC) 33 generates a predetermined oscillation signal.

The error timer 34 interrupts the operation if a predetermined error occurs.

### 1-2. Example of Arrangement of NOR Flash Memory

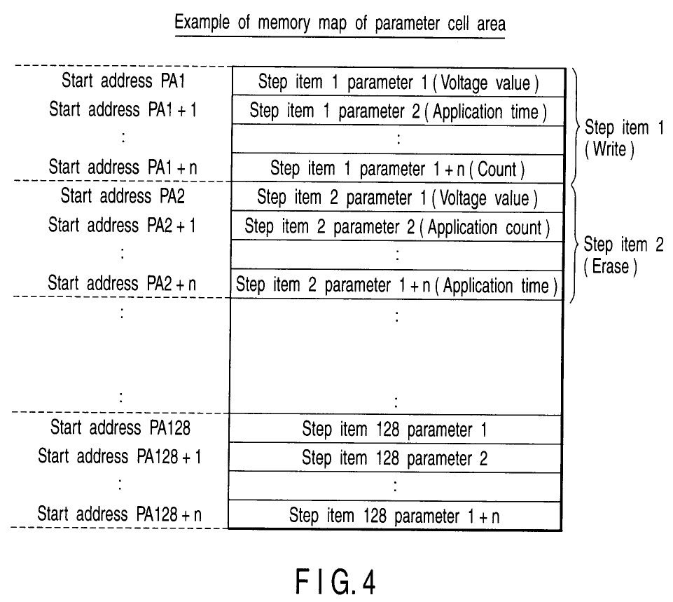

An example of the arrangement of the NOR flash memory 11 according to this embodiment will be explained in more detail below with reference to FIGS. 2 to 4. FIG. 3 shows an example of the memory map of a step cell area. FIG. 4 shows an example of the memory map of a parameter cell area.

As shown in FIG. 2, the NOR flash memory 11 has the register Reg and memory cell array 32.

The register Reg temporarily holds data, addresses, commands, and the like input to and output from the bus 19.

The memory cell array 32 has a general area 35 and CFI (Common Flash memory Interface) area 36, and performs read, write, and erase of data and the like as nonvolatile data by using the memory cell transistors (not shown).

The general area 35 stores, e.g., user data such as voice data input from the input buffer 21 and the like.

The CFI area 36 is a management area that is limited in at least read more than the general area 35, and includes a step cell area 38 and parameter cell area 39. The CFI area 36 may also be limited in, e.g., a write operation and erase operation, in addition to a read operation, more than the general area 35.

The step cell area 38 stores step items and parameter start addresses. The step items and parameter start addresses are used in a BIST (to be described later). Parameter start addresses PA are obtained from the outside via the BIST interface 26. FIG. 3 shows the memory map of the step cell area 38.

As shown in FIG. 3, step items 1 to 128 and parameter start addresses PA1 to PA128 are stored in step operation number storage addresses TA1 to TA128.

In this embodiment, step item 1 and parameter start address PA1 are stored in step operation number storage address TA1, and step item 1 is a write operation. Similarly, step item 2 stored in step operation number storage address TA2 is an erase operation, and step item 3 stored in step operation number storage address TA3 is a read operation.

The parameter cell area 39 stores step item parameters that have addresses (to be described later) corresponding to the parameter start addresses, and define the individual step items described above. The step item parameters are used in the BIST (to be described later). FIG. 4 shows the memory map of the parameter cell area 39.

As shown in FIG. 4, step item parameters from step item 1 parameter 1+n to step item 128 parameter 128+n are respectively stored in parameter start addresses PA1+n to PA128+n (n is a natural number). In this manner, a plurality of parameter start addresses PA are defined for one step item, and step item parameters corresponding to parameter start addresses PA are defined.

In this embodiment, parameter start addresses PA1 to PA1+n are defined for step item 1 (write), and step item 1 parameters 1 to 1+n are respectively defined for parameter start addresses PA1 to PA1+n. For example, step item 1 parameter 1 is a parameter of the voltage value of the write operation, step item 1 parameter 2 is a parameter of the application time of the write operation, . . . , step item 1 parameter 1+n is a parameter of the application count of the write operation.

During the BIST, the controller 12 performs, on the generation area 35 and the like of the NOR flash memory 11, test steps corresponding to step items 1 to 128 defined by these parameters. For example, when conducting the BIST at start address PA1, the controller 12 controls the voltage of the power supply circuit 28 so as to perform, on the generation area 35 and the like, the test step (write operation) corresponding to parameter 1 (voltage value) of step item 1 (write operation).

Likewise, parameter start addresses PA2 to PA2+n are defined for step item 2 (erase), and step item 2 parameters 1 to 1+n are respectively defined for parameter start addresses PA2 to PA2+n. For example, step item 2 parameter 1 is a parameter of the voltage value of the erase operation, step item 2 parameter 2 is a parameter of the application count of the erase operation, . . . , step item 2 parameter 1+n is a parameter of the application time of the erase operation.

### <2. Self-Test (BIST) Method>

elf-test method of the memory device according to this embodiment will be explained below.

### 2-1. Self-Test Method (When Step Items Have No Changes or the Like)

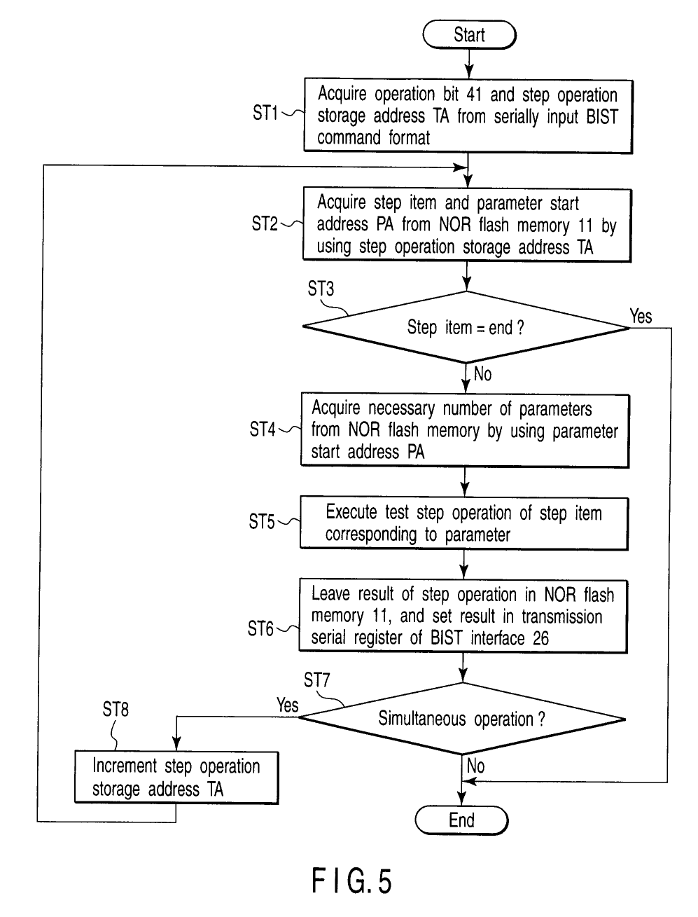

First, a self-test method when the step items have no changes or the like will be explained with reference to FIGS. 5 to 7. The explanation will be made in accordance with a flowchart shown in FIG. 5.

### (Step ST1)

As shown in FIG. 5, the BIST interface 26 first receives a BIST command (test command) from the outside (a BIST tester), and holds this BIST command in the internal serial register of the BIST interface 26. After that, the BIST interface 26 transmits the BIST command to the command analyzer 27. More specifically, the BIST interface 26 is a serial input/output circuit and connected to connection pins to be used from the input/output buffer 25 or input buffer 21. In this embodiment, three types of connection pins, i.e., a shift clock pin, input/output switching pin, and data pin are connected.

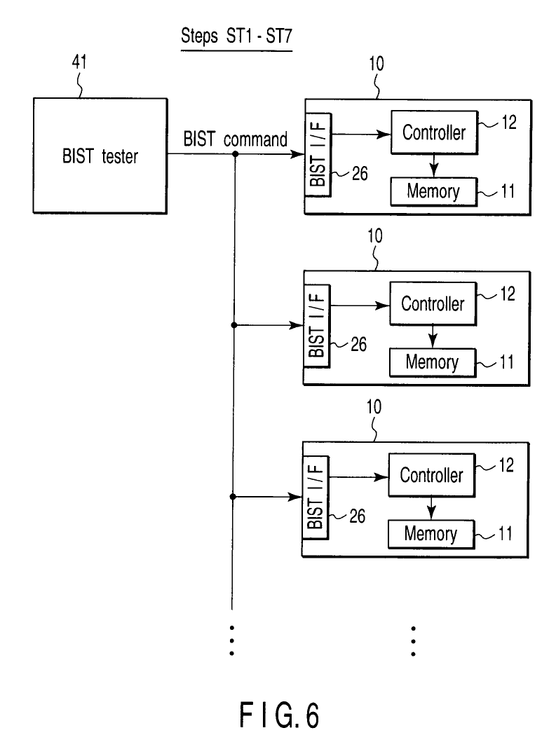

In this BIST as shown in FIG. 6, one BIST tester 41 can test a plurality of memory devices 10. The BIST must be conducted by using a small number of input/output pins for the memory chips (memory devices) 10 to be tested. Therefore, the BIST interface 26 has a serial input/output configuration.

Subsequently, the command analyzer 27 analyzes the shift register value of the received BIST command, and transmits the analyzed value to the controller 12, thereby allowing the controller 12 to activate the BIST operation as an interrupt.

In this way, to directly activate the CPU 15 in the controller 12, the interrupt activation described above is performed as an interrupt from the analyzer 27 having analyzed the shift register value of the received BIST command, thereby activating the CPU 15.

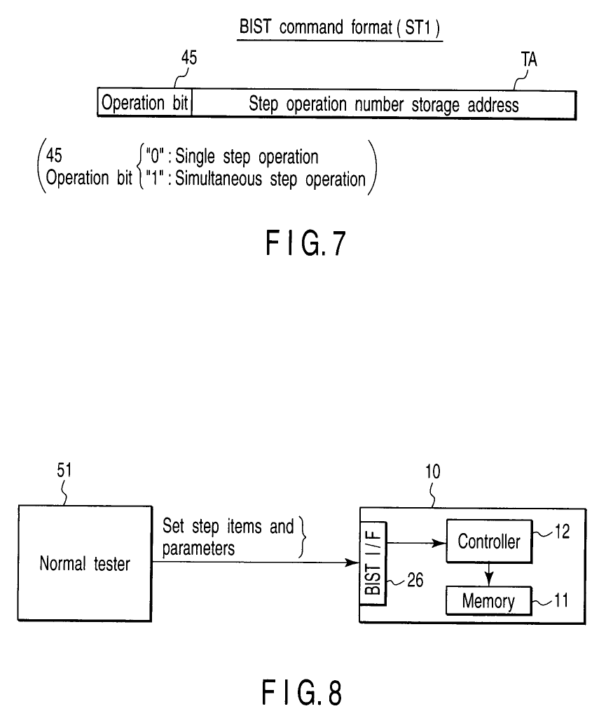

FIG. 7 shows the command format of the BIST command. As shown in FIG. 7, this command format includes an operation bit 45 and step operation number storage address TA.

The operation bit 45 is one bit, and has the meanings of a single step operation and simultaneous step operation. In this embodiment, an operation bit “0” means the single step operation, and an operation bit “1” means the simultaneous step operation.

The single step operation means an operation by which the BIST is terminated after a step operation designated by step operation number storage address TA is executed.

The simultaneous step operation means an operation by which until a step operation designated by step operation number storage address TA fails, step operation number storage address TA is incremented (address TA1→address TA2→address TA3→ . . . →address TA128), and corresponding step items are sequentially advanced (step item 1 (write)→step item 2 (erase)→step item 3 (read)→ . . . →step item 128).

Subsequently, the controller 12 acquires the operation bit 45 and step operation number storage address TA from the received BIST command.

### (Step ST2)

If necessary, the CPU 15 in the controller 12 reads out control software for the BIST operation from the instruction memory 16, and executes the following operation.

That is, the CPU 15 in the controller 12 accesses the step cell area 38 of the NOR flash memory 11 by using acquired step operation storage address TA, and acquires the step item and parameter start address PA corresponding to step operation storage address TA.

For example, the CPU 15 in the controller 12 accesses the step cell area 38 by using obtained step operation storage address TA1, and acquires step item 1 (write operation) and parameter start address PA1 corresponding to step operation storage address TA1.

### (Step ST3)

Subsequently, the CPU 15 in the controller 12 determines whether the obtained step item is the end. If the step item is the end, the controller 12 terminates the BIST. If the step item is not the end, the controller 12 performs the next step.

Whether the step item is the end is determined by checking whether step item 128 of the like is stored as an address meaning the end. Thus, the controller 12 stores a number meaning the end in step operation number storage address PA of the last step item to be executed. If the step operation does not fail, therefore, the controller 12 reads out the step item and terminates the BIST if the number means the end.

### (Step ST4)

Then, the CPU 15 in the controller 12 uses parameter start address PA to obtain necessary step item parameters from the parameter cell area 38 of the NOR flash memory 11.

For example, the CPU 15 uses parameter start address PA1 to acquire parameters 1 (voltage value) to 1+n (application count) of necessary step item 1 (write operation) from the parameter cell area 38.

### (Step ST5)

Next, the CPU 15 in the controller 12 executes, on the NOR flash memory 11, the test step operation of the step item corresponding to the parameters.

For example, the CPU 15 executes, on the NOR flash memory 11, the test step operation of step item 1 (write operation) corresponding to parameters 1 (voltage value) to 1+n (application count). To this end, the CPU 15 controls the voltage value of the power supply circuit 28 to perform step item 1 (write operation) corresponding to predetermined parameter 1 (voltage value), thereby performing a write operation in, e.g., the general area 35 of the NOR flash memory 11.

### (Step ST6)

Subsequently, the CPU 15 in the controller 12 stores the result of the step item in step ST5 into, e.g., the general area 35 of the NOR flash memory 11, and transmits the result of the step item in step ST5 to the BIST interface 26.

The BIST interface 26 having received the result of the test item sets the result of the above step operation in the serial register of the BIST interface 26.

### (Step ST7)

Then, the CPU 15 in the controller 12 checks whether the operation bit 45 of the previously received BIST command is the simultaneous step operation (“1”).

If the operation bit 45 is not the simultaneous step operation (“0”), the CPU 15 terminates the BIST.

### (Step ST8)

On the other hand, if the operation bit 45 is the simultaneous step operation (“1”), the CPU 15 increments step operation number storage address TA (advances the address by one), and repeats the same operations as in steps ST2 to ST6.

For example, if the operation bit 45 is the simultaneous step operation (“1”), the CPU 15 repeats steps ST2 to ST6 so as to perform step item 2 (erase operation) corresponding to address TA2 obtained by incrementing operation number storage address TA1.

### 2-2. Examples of Changes of Step Items and Parameters

As described above, the order of the step items and step operation number storage addresses TA stored in the step cell area 38 is the operation sequence of the BIST. In addition, the step item parameters stored in the parameter cell area 39 define the detailed test contents of the step items and the order of the contents.

In the BIST of the NOR flash memory 11, many test steps must be performed to sort a number of failure modes such as a write characteristic abnormality, erase characteristic abnormality, retention (charge holding) defect, endurance (repetitive rewrite) defect, disturbance defect, and fabrication process defect. In addition, step items 1 (write) to 128 themselves or parameters 1 to 1+n for executing step items 1 (write) to 128 are normally changed many times in order to increase the yield.

Accordingly, examples of changes of the step items and parameters will be explained below with reference to FIGS. 8 to 10.

FIG. 8 shows the way the step sequence of the BIST described above is changed. As shown in FIG. 8, the controller 12 sets the changed step items transmitted from a normal tester 51 in the step cell area 38 of the NOR flash memory 11.

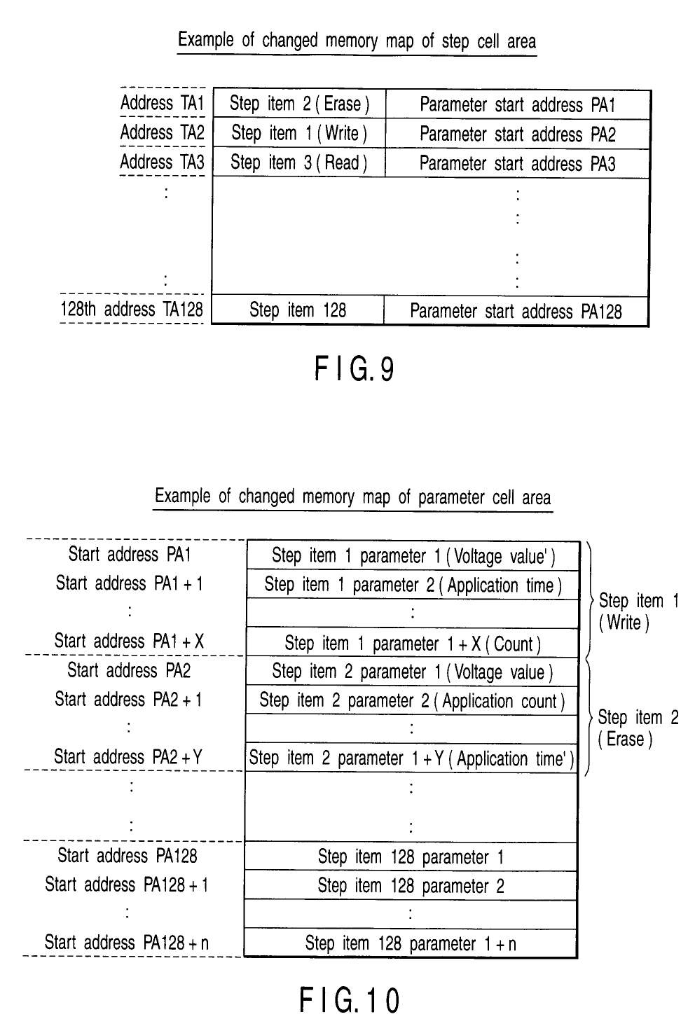

FIG. 9 shows an example of the changed memory map of the step cell area 38. As shown in FIG. 9, the controller 12 sets the step items in the step cell area 38 so as to switch step item 2 (erase) and step item 1 (write). This setting makes it possible to conduct a BIST (steps ST1 to ST8) by which step item 2 (erase) and step item 1 (write) are switched.

Consequently, the order of the step sequence of the BIST can be changed.

Similarly, it is also possible to change or delete the contents of the step sequence of the BIST by changing or deleting the contents of the changed step items transmitted from the normal tester 51.

Furthermore, FIG. 8 also shows the way the contents of individual step items are changed by changing the step item parameters of the BIST.

As shown in FIG. 8, the controller 12 sets the changed step item parameters transmitted from the normal tester 51 into the parameter cell area 39 of the NOR flash memory 11.

FIG. 10 shows an example of the changed memory map of the parameter cell area 39. As shown in FIG. 10, the controller 12 sets the step item parameters in the parameter cell area 39 so as to rewrite the step item parameters of step item 1 (write) and step item 2 (erase).

For example, in step item 1 (write), it is possible to execute the test item by increasing the number of parameters to X (X>n), and set parameter 1 (voltage value’) by which data is written by a lower write voltage.

For example, in step item 2 (erase), it is possible to execute the test item by decreasing the number of parameters to Y (Y<n), and set parameter 1+Y (application time’) by which data is erased using a longer time.

This makes it possible to freely change the contents of the step items (step items 1 to 128) of the BIST.

Likewise, the contents of the step items of the BIST can be deleted by deleting the changed parameters transmitted from the normal tester 51.

As described above, the step items and the parameters of the step items can be, e.g., changed by rewriting the contents of the step cell area 38 and parameter cell area 39.

### <3. Effects of This Embodiment>

The memory device and its self-test method according to this embodiment can achieve effects (1) to (3) below.

(1) Even when test steps are changed, it is possible to prevent circuit correction and reduce the fabrication cost.

As described above, the memory device 10 according to this embodiment has the NOR flash memory 11 that stores step items 1 to 128 and parameter start addresses PA1 to PA128 in the step cell area 38, and stores parameters 1 to 1+n corresponding to parameter start addresses PA1 to PA128 in the parameter cell area 39. The memory device 10 also has, in the same chip, the controller (dedicated microcomputer) 12 configured to perform, on the NOR flash memory 11, test steps defined by parameters 1 to 1+n and corresponding to step items 1 to 128.

When conducting the BIST (self-test) of the NOR flash memory 11, the controller (microcomputer) 12 reads out step items 1 to 128, parameter start addresses PA1 to PA128, and parameters 1 to 1+n, and performs step items 1 to 128 corresponding to parameters 1 to 1+n (steps ST1 to ST8).

The order or contents of the test step operations can be changed by rewriting the order of step items 1 to 128 or the contents of the parameters (FIG. 8). Since the test steps can be changed by software as described above, it is possible to prevent the occurrence of circuit correction and reduce the fabrication cost.

When performing circuit correction, for example, a large amount of masks must be changed, and each mask costs, e.g., about a few hundred thousand to a few million yen. This embodiment reduces this fabrication cost.

When changing the step items of the BIST, for example, as shown in FIG. 8, the controller 12 sets the changed step items transmitted from the normal tester 51 in the step cell area 38 of the NOR flash memory 11.

FIG. 9 shows an example of the changed memory map of the step cell area. As shown in FIG. 9, the controller 12 can set the step items in the step cell area 38 so as to switch step item 2 (erase) and step item 1 (write). By thus setting the step items, it is possible to perform, e.g., a BIST (steps ST1 to ST8) in which step item 2 (erase) and step item 1 (write) are switched. This makes it possible to change the order of the step items of the BIST without any circuit correction.

Furthermore, when changing the contents of the step items of the BIST, for example, the controller 12 sets the changed step item parameters transmitted from the normal tester 51 in the parameter cell area 39 of the NOR flash memory 11.

FIG. 10 shows an example of the changed memory map of the parameter cell area 39. As shown in FIG. 10, the controller 12 can set the step item parameters in the parameter cell area 39 so as to rewrite the step item parameters of step item 1 (write) and step item 2 (erase).

In step item 1 (write), for example, it is possible to perform the test item by increasing the number of parameters to X (X>n), and set parameter 1 (voltage value’) by which data is written by a lower write voltage.

In step item 2 (erase), for example, it is possible to perform the test item by decreasing the number of parameters to Y (Y<n), and set parameter 1+Y (application time’) by which data is erased using a longer time.

Accordingly, it is possible to change the contents of the individual step items (step items 1 to 128) of the BIST without any circuit correction. Similarly, the contents of the individual step sequences of the BIST can be deleted by deleting the changed parameters transmitted from the normal tester 51.

As described above, the step items and the parameters of the step items can be, e.g., changed by rewriting the contents of the step cell area 38 and parameter cell area 39.

(2) This embodiment is advantageous in reducing the test time.

As described above, the memory device 10 of this embodiment can prevent circuit correction even when test steps are changed.

Also, the step items and step item parameters can be, e.g., changed by rewriting the contents of the step cell area 38 and parameter cell area 39, so no circuit correction is necessary.

Even when the test steps are changed, therefore, the contents of the test steps can be easily changed. This is advantageous in reducing the test time.

(3) This embodiment can improve the reliability.

The memory device 10 according to this embodiment comprises the NOR flash memory 11 and the controller (microcomputer) 12 for controlling the BIST in the same chip.

Since the NOR flash memory 11 and controller 12 are sealed in the same chip, they can be protected from, e.g., external temperature changes and humidity changes, so the reliability improves. In addition, the area occupied by the NOR flash memory 11 and controller 12 can be reduced because they are sealed in the same chip.

Note that the above embodiment is explained by taking a NOR flash memory as an example of nonvolatile memories. However, the present invention is similarly applicable to other nonvolatile memories such as a NAND flash memory, MRAM (Magnetic Random Access Memory), and FeRAM (Ferroelectric Random Access Memory), as well as the NOR flash memory.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A memory device comprising:
a nonvolatile memory which stores a step item, a parameter start address, and a parameter which has an address corresponding to the parameter start address and defines the step item; and
a controller which performs, on the nonvolatile memory, a test step corresponding to the step item defined by the parameter, the controller being formed in the same chip as the nonvolatile memory.

2. The device according to claim 1, further comprising, in the chip, an interface which transmits, to the controller, a test command formatted to have an operation bit and a step operation address corresponding to the step item and the parameter start address.

3. The device according to claim 2, further comprising a command analyzer which analyzes the test command transmitted from the interface, and transmits the analyzed test command to the controller.

4. The device according to claim 1, wherein the controller includes an instruction memory which stores a control program for the test step, and a CPU which reads out the control program and executes the step item.

5. The device according to claim 1, wherein the nonvolatile memory has a general area, and a management area limited in at least read more than the general area.

6. The device according to claim 5, wherein the step item and the parameter start address are stored in a first area of the management area.

7. The device according to claim 6, wherein the parameter is stored in a second area of the management area.

8. The device according to claim 1, further comprising a sense amplifier which amplifies write/read data from the nonvolatile memory.

9. The device according to claim 8, further comprising a bus to which the sense amplifier transmits the write/read data.

10. The device according to claim 1, further comprising a buffer which temporarily holds external data, an external address, and an external command.

11. The device according to claim 1, further comprising a power supply circuit which generates a power supply voltage for driving circuits of the device.

12. The device according to claim 1, further comprising a fuse which stores initial data as nonvolatile data.

13. The device according to claim 1, further comprising an oscillator which generates a predetermined oscillation signal.

14. The device according to claim 1, further comprising an error timer which interrupts an operation if an error occurs.

15. A built in self-test method with a memory device including, in the same chip, a nonvolatile memory which stores a step item, a parameter start address, and a parameter which has an address corresponding to the parameter start address and defines the step item, and a controller, the method comprising causing the controller to perform, on the nonvolatile memory, a test step corresponding to the step item defined by the parameter.

16. The method according to claim 15, further comprising, before the test step is performed on the nonvolatile memory, causing the device to acquire an operation bit and a step operation address from an externally input command.

17. The method according to claim 16, further comprising, after the operation bit and the step operation address are acquired, causing the controller to acquire a step item and a parameter start address from the nonvolatile memory by using the step operation address.

18. The method according to claim 17, further comprising, after the step item and the parameter start address are acquired, causing the controller to acquire a parameter from the nonvolatile memory by using the parameter start address.

19. The method according to claim 15, further comprising, after the test step is performed on the nonvolatile memory, causing the controller to leave a result of the test step behind in the nonvolatile memory.
